(19) United States
(12) Patent Application Publication
(10) Pub. No.: US 2014/0015536 A1
(43) Pub. Date: Jan. 16, 2014

(54) Battery System for Measuring Battery Module Voltages

(71) Applicants: Stefan Butzmann, Beilstein (DE); Holger Fink, Stuttgart (DE)

(72) Inventors: Stefan Butzmann, Beilstein (DE); Holger Fink, Stuttgart (DE)

(73) Assignees: Samsung SDI Co., Ltd., Yongin-si, Gyeonggi-do (KR); Robert Bosch GmbH, Stuttgart (DE)

(21) Appl. No.: 13/825,274

(22) PCT Filed: Aug. 10, 2011
(86) PCT No.: PCT/EP11/63729

§ 371 Date: Oct. 2, 2013

(30) Foreign Application Priority Data
Sep. 20, 2010 (DE) 102010041053.5

(51) Int. Cl. G01R 31/36

(52) U.S. Cl. CPC G01R 31/3606
USPC 324/434

(57) ABSTRACT

A battery system includes at least one module which comprises a large number of battery cells. Each module has an associated cell voltage detection unit which is connected to an evaluation unit by a communications bus. Each module additionally includes a module voltage detection circuit which is connected to the evaluation unit. The disclosure also relates to a method for monitoring a battery system having at least one module comprising a large number of battery cells. A voltage of each of the battery cells is detected and supplied to an evaluation unit by a cell voltage detection unit. In addition, a module voltage is separately detected and supplied to the evaluation unit. The disclosure also describes a motor vehicle having a battery system. The battery system is connected to a drive system of the motor vehicle.

The present invention relates to a battery system and also to a method for monitoring a battery system and to a motor vehicle having the inventive battery system.

### PRIOR ART

It is becoming apparent that in future there will be increased use of new battery systems for static applications, for example in the case of wind power installations, and vehicles, for example in hybrid and electric vehicles, said battery systems being subject to very great demands in terms of reliability.

The background to these great demands is that failure of the battery system can result in failure of the overall system. By way of example, failure of the traction battery in an electric vehicle results in a “breakdown”. Furthermore, the failure of a battery can result in a safety-related problem. In wind power installations, for example, batteries are used in order to protect the installation against inadmissible operating states in high wind by virtue of rotor blade adjustment.

The block diagram for a battery system based on the prior art is shown in FIG. 1. A battery system, denoted as a whole by 100, comprises a multiplicity of battery cells 10 which are combined in a module 24. Furthermore, a charging and isolator device 12 which comprises an isolator switch 14, a charging switch 16 and a charging resistor 18 is provided. In addition, the battery system 100 may comprise an isolator device 20 having an isolator switch 22.

For safe operation of the battery system 100, it is absolutely necessary for each battery cell 10 to be operated within a permitted operating range (voltage range, temperature range, current limits). If a battery cell 10 is outside these limits, it needs to be removed from the cell complex. When the battery cells 10 are connected in series (as shown in FIG. 1), failure of a single battery cell 10 therefore results in failure of the whole battery system 100.

Particularly in hybrid and electric vehicles, batteries using lithium ion or nickel metal hybrid technology are used which have a large number of electrochemical battery cells connected in series. A battery management unit is used for monitoring the battery and is intended to ensure not only safety monitoring but also the longest possible life. By way of example, a cell voltage sensing unit is thus used.

FIG. 2 shows the known use of such a cell voltage sensing unit.

FIG. 2 shows an architecture which is known from the prior art for typical cell voltage sensing. In this case, each module 24 with its battery cells 10 has an associated cell voltage sensing unit 26. The cell voltage sensing unit 26 comprises a multiplexer 28 which senses the voltage of each of the individual battery cells 10 by using a number of channels 30 which corresponds to the number of battery cells 10. The multiplexer 28 is connected to a gateway 34 via an analog-to-digital converter 32, said gateway being coupled to a communication bus 36. The communication bus 36 has a central microcontroller 38 connected to it. This central microcontroller 38 can therefore be used to sense and evaluate the voltages of the individual battery cells 10. The microcontroller 38 may be part of a battery management unit.

As clarified by FIG. 2, a plurality of modules 24 having battery cells 10 may be arranged in series in this case, said modules each having a dedicated cell voltage sensing unit 26.

The multiplexer 28 has auxiliary inputs 40, which are indicated here, which are known to be able to be used for temperature measurement by virtue of resistance values of NTC resistors being able to be sensed.

### DISCLOSURE OF THE INVENTION

The invention provides a battery system having at least one module which has a multiplicity of battery cells, wherein each module has an associated cell voltage sensing unit which is connected to an evaluation unit by means of a communication bus, wherein each module additionally comprises a module voltage sensing circuit which is connected to the evaluation unit. This advantageously allows the cell voltages measured by means of the cell voltage sensing unit to be verified by virtue of the voltages of the individual modules additionally being separately measured and separately transmitted to the evaluation unit. The evaluation unit is therefore rendered able to compare the cell voltages which have been ascertained by means of the cell voltage sensing unit and which have been transmitted in digitized form via the communication bus with the additional information which is provided by means of the module voltage sensing unit. In particular, it is thus also possible to establish and assess plausibility for the cell voltage information delivered by means of the cell voltage sensing unit.

In one preferred embodiment of the invention, the module voltage sensing unit comprises a voltage-dependent frequency generator, which is preferably an oscillator. This makes it a particularly simple matter to sense an overall module voltage and to make it available to the evaluation unit following conditioning. The evaluation unit is therefore easily able to read in the frequency value received, which corresponds to the measured module voltage, and to compare it with the signals received from the cell voltage sensing unit.

In addition, in one preferred embodiment of the invention, the oscillator is capacitively coupled to the evaluation unit. This advantageously allows use to be made of the effect that capacitive coupling increases as frequency rises. This makes it a simple matter to assist the evaluation. In addition, it is not possible for spurious voltages to influence the evaluation unit via the module voltage sensing circuit.

The invention also provides a method for monitoring a battery system having at least one module having a multiplicity of battery cells, in which a voltage of each of the battery cells is sensed and is likewise supplied to an evaluation unit via a cell voltage sensing unit, wherein additionally a module voltage is separately sensed and supplied to the evaluation unit. This makes it a simple matter to verify the information provided by the cell voltage sensing unit. The separate additional sensing of the module voltage provides the evaluation device with a further opportunity to ensure the reliability of the battery system as a whole.

Preferably, a frequency signal that is proportional to the module voltage is generated and this frequency signal is supplied to the evaluation unit. This makes it a simple matter to couple the module voltage signal measured in analog form to the digitally operating evaluation unit. The frequency signal can easily be evaluated as a binary signal.

A further aspect of the invention relates to a motor vehicle which comprises the inventive battery system.

Overall, the effect which can be achieved by the inventive battery system and the invention method is that the reliability of the battery system can be checked and any malfunctions can be recognized in good time in order to avoid consequential damage as a result of battery systems operating unreliably.

### DRAWINGS

Exemplary embodiments of the invention are explained in more detail with reference to the drawings and the description below. In the drawings:

FIG. 1 shows a battery system based on the prior art,

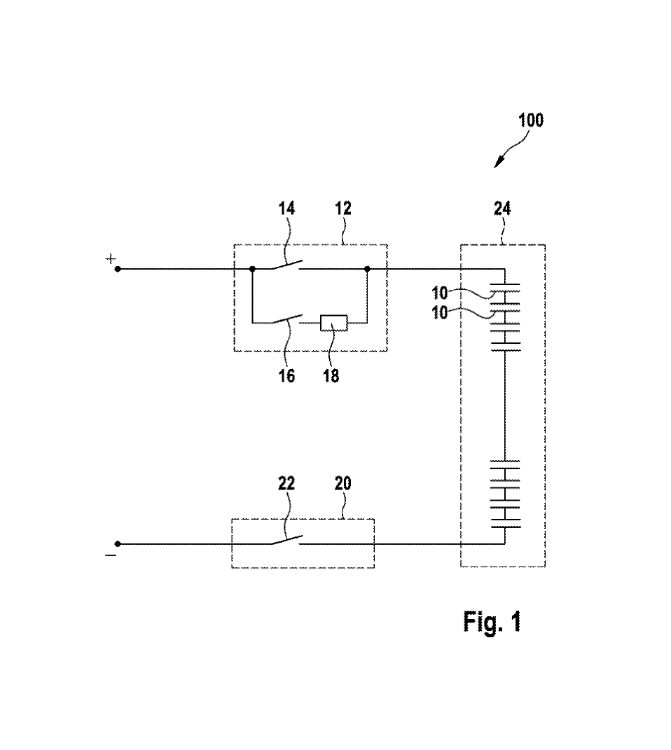

FIG. 2 shows an architecture of a cell voltage sensing unit based on the prior art, and

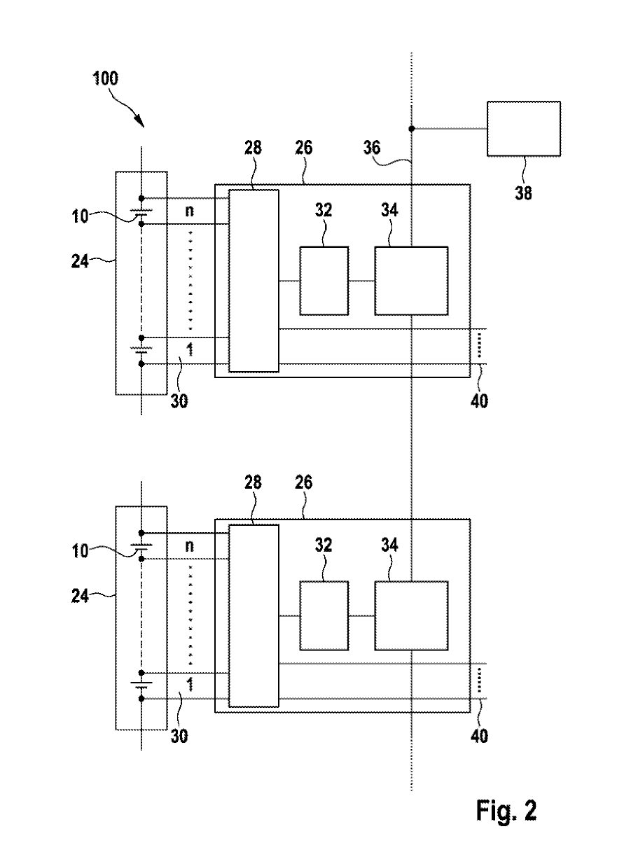

FIG. 3 shows an inventive battery system having additional battery module voltage measurement.

### EMBODIMENTS OF THE INVENTION

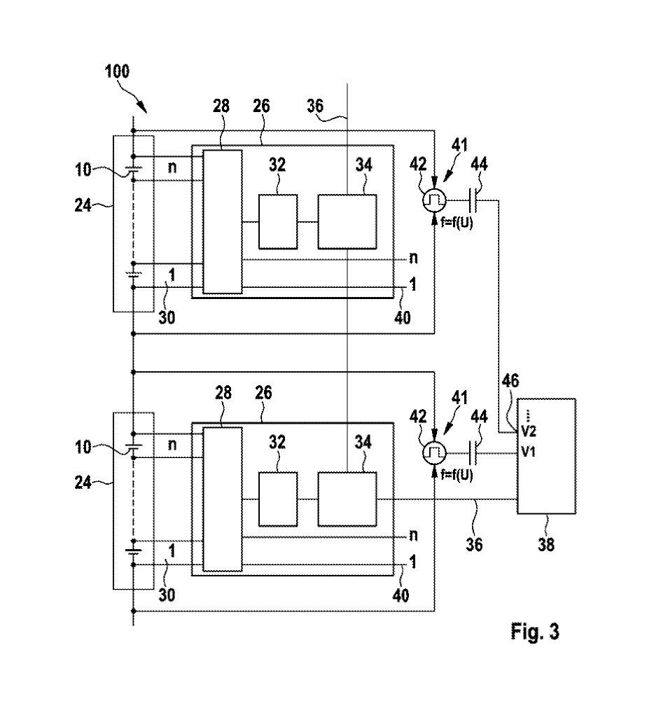

FIG. 3 shows a battery system 100 based on the invention. A multiplicity of battery cells 10 are connected in series and are combined in a module 24. A multiplexer 28 brings together the cell voltages of the individual battery cells 10 and supplies them to a communication bus 36 via an analog-to-digital converter 32 and a gateway 34. The microcontroller 38 is used to perform the voltage evaluation in a manner which is known per se.

FIG. 3 shows two modules 24 by way of example which each have a multiplicity of battery cells 10. According to further exemplary embodiments, not shown, a plurality of the modules 24 may also be connected up in series or in parallel with one another.

Each module 24 has an associated module voltage sensing circuit 41. The module voltage sensing circuit 41 taps off the voltage which is present across the module 24 and supplies it to an oscillator 42. The oscillator 42 is capacitively coupled to inputs 46 of the evaluation circuit 38 by means of one capacitor circuit 44 in each case.

The module voltage sensing circuit 41 is used to tap off the voltage across the entire module 24 and to convert it into a signal that is proportional to the frequency. This signal is then provided for the evaluation circuit 38 by means of the capacitive coupling 44. At the same time, the evaluation circuit 38 receives the information from the cell voltage sensing units 26 via the communication bus 36. Appropriate association and comparison of the signals which are provided by means of the communication bus 36 and the inputs 46 can be used to perform a comparison and appropriate evaluation. In this case, the module voltage is calculated from the frequency measured by means of the oscillator 42 and is compared with the cell voltages measured by means of the cell voltage sensing units 26.

1. A battery system comprising:
at least one module including (i) a plurality of battery cells, (ii) an associated cell voltage sensing unit which is connected to an evaluation unit a communication bus, and (iii) a module voltage sensing circuit which is connected to the evaluation unit.

2. The battery system as claimed in claim 1, wherein the module voltage sensing circuit comprises a voltage-dependent frequency generator.

3. The battery system as claimed in claim 2, wherein the frequency generator is an oscillator.

4. The battery system as claimed in claim 3, wherein the oscillator is capacitively coupled to the evaluation unit.

5. A method for monitoring a battery system having at least one module including a plurality of battery cells, comprising:
sensing a voltage of each battery cell of the plurality of battery cells;
supplying the sensed voltage to an evaluation unit via a cell voltage sensing unit;
separately sensing a module voltage; and
supplying the module voltage to the evaluation unit.

6. The method as claimed in claim 5, further comprising:
generating a frequency signal that is proportional to the module voltage: and
supplying the frequency signal to the evaluation unit.

7. A motor vehicle comprising:
a drive system; and
a battery system connected to the drive system, the battery system including at least one module having (i) a plurality of battery cells, (ii) an associated cell voltage sensing unit which is connected to an evaluation unit by a communication bus, and (iii) a module voltage sensing circuit which is connected to the evaluation unit.
